(19) United States
(12) Patent Application Publication
(10) Pub. No.: US 2007/0090534 A1
(43) Pub. Date: Apr. 26, 2007

(54) Semiconductor module including a plurality of IC chips therein

(76) Inventors: Hironori Iwasaki, Nagano (JP); Takao Ono, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 11/582,958

(22) Filed: Oct. 19, 2006

(30) Foreign Application Priority Data
Oct. 20, 2005 (JP) 2005-306079

(51) Int. Cl. H01L 23/52

(52) U.S. Cl. 257/777

(57) ABSTRACT

A semiconductor module includes a driver IC chip and a plurality of memory IC chips on a common wiring board. Some of the memory IC chips nearer to the driver IC chip than the other memory IC chips are mounted on an interposer substrate mounted on the wiring board, providing a uniform line length among a species of signal lines for the memory IC chips.

### BACKGROUND OF THE INVENTION

(a) Field of the Invention

The present invention relates to a semiconductor module and, more particularly, to a semiconductor module including a plurality of IC chips mounted on a wiring board.

(b) Description of the Related Art

In a typical semiconductor module, a common wiring board, such as a printed circuit board, mounts thereon a plurality of IC chips which are connected together by interconnect lines formed within the wiring board. FIGS. 11A and 11B exemplify the top and bottom surfaces, respectively, of a conventional semiconductor module including a plurality of memory IC chips.

The semiconductor module, generally designated by numeral 40, includes a driver IC chip 12 and a plurality of memory IC chips 13 (13-1 to 136) driven by the driver IC chip 12, all of which are mounted on a common wiring board 211. The driver IC chip 12 is mounted at the center of the top surface of the wiring board 11, whereas the memory IC chips 13 are mounted on the top and bottom surfaces of the wiring board 11 in a symmetric arrangement. In FIGS. 11A and 11B, terminals 21 of the driver IC chip 12 and terminals 22 of the memory IC chips 13 are depicted for a better understanding of the structure of the IC chips, although those terminals 21, 22 do not appear on the top surface of the driver IC chips 12, 13.

FIG. 12 shows the semiconductor module 40 shown in FIGS. 11A and 11B in a sectional view taken along line XII-XII in FIG. 11A. The thick line 23 in FIG. 2 depicts a specific common signal line connecting the driver IC chip 12 with the memory IC chips 13 in common. The specific common signal line 23 is also shown by dotted line in FIGS. 11A and 11B.

The driver IC chip 12 is mechanically and electrically coupled to the wiring board 11 via a plurality of solder balls 27 formed on respective terminals 21 of the driver IC chip 12. Similarly, the memory IC chips 13 are mechanically and electrically coupled to the wiring board 11 via a plurality of solder balls 27 formed on respective terminals 22 of the memory IC chips 13. The wiring board 11 includes a plurality of insulation layers and a plurality of layers of interconnect lines 23 formed alternately with the insulation layers.

The wiring board 11 includes therein a plurality of via-holes 24, each of which receives therein a via-line 25 deposited on the sidewall of the via-holes 24 by a plating technique. The via-line 25 connects a solder ball 27 formed on the top surface of the wiring board 11 with a solder ball 27 formed on the bottom surface thereof. The interconnect lines 23 connecting together the driver IC chip 12 and the memory IC chips 13 include dedicated signal lines each connecting the driver IC chip 12 with a single memory IC chip 13 and common lines, such as the specific common signal lines 23 shown in FIG. 2, connecting the driver IC chip 12 with the plurality of memory IC chips 13 in common.

The common lines each connect the memory IC chips 13 to the driver IC chip 12 with respective distances of the memory IC chips 13 apart from the driver IC chip 12. The different distances between the memory IC chips 13 and the driver IC chip 12 incur different propagation delays of the common signal transferred through the common lines, and may cause a signal interference at the terminals of one of the memory IC chips 13 due to the reflecting wave reflected from the terminals of another memory IC chip 13. This may cause a distortion of the original rectangular waveform of the common signal, and incur an error or malfunction in operation of the semiconductor module 40. This malfunction especially occurs in the memory IC chips 13-1, 13-4 etc. disposed nearer to the driver IC chip 12 than the other memory IC chips 13-3, 136 etc. Thus, it is desired that the common line in the wiring board 11 have a uniform path length among the memory IC chips 13 with respect to the driver IC chip 12 for achieving a uniform propagation delay.

For achieving the uniform path length for the memory IC chips 13 with respect to the driver IC chip 12, a configuration may be employed wherein the common lines have a detour path within the wiring board 11 for the memory IC chips 13-1, 13-4 etc, disposed nearer to the driver IC chip 12. This technique is described in Patent Publication JP-2001-237315A, for example.

In a semiconductor module including a plurality of memory IC chips, the number of signal lines between the driver IC chip 12 and the memory IC chips 13 as well as the number of species of the signal lines has increased, together with the development for a higher operational speed of the memory IC chips 13. In addition, the external lines, which are conventionally connected directly to the memory IC chips 13, are connected to the memory IC chips 13 via the driver IC chip 12 in some cases. Thus, the number of terminals of the driver IC chip 12 has significantly increased.

A portion of the wiring board 11 on which the driver IC chip 12 is mounted in FIGS. 11A and 11B has a higher density of the signal lines 23 and via-lines 25. This prevents the common lines from having a detour path in the wiring board 11 near the driver IC chip 12 without increasing the number of interconnect layers and thus increasing the thickness and cost of the wiring board 11.

### SUMMARY OF THE INVENTION

In view of the above problems in the conventional technique, it is an object of the present invention to provide a semiconductor module wherein the length of the interconnect lines disposed between IC chips can be adjusted without increasing the number of interconnect layers in the wiring board.

The present invention provides a semiconductor module including a wiring board, an interposer substrate mounted on the wiring board, and a plurality of IC chips including at least one first IC chip directly mounted on the wiring board and at least one second IC chip mounted on the interposer substrate and connected to interconnect lines in the wiring board via the interposer substrate.

In accordance with the semiconductor module of the present invention, the interposer substrate may provide a uniform path length of the interconnect lines among the IC chips without increasing the thickness or cost of the wiring board.

The above and other objects, features and advantages of the present invention will be more apparent from the following description, referring to the accompanying drawings.

### BRIEF DESCRIPTION OF THE DRAWINGS

FIGS. 1A and 1B are top and bottom plan views, respectively, of a semiconductor module according to as first embodiment of the present invention.

FIG. 2 is a sectional view taken along line II-II in FIG. 1A.

FIG. 3 is an enlarged sectional view of a portion of the semiconductor module, showing the detail of the interposer substrate.

FIG. 4 is a top plan view of the interposer substrate shown in FIG. 4.

FIG. 5 is a schematic circuit diagram showing the path length of a common line connected between the terminal of the driver IC chip and the terminals of the memory IC chips.

FIGS. 6A to 6C are sectional views of a portion of the interposer substrate of FIG. 3 in consecutive steps of fabrication thereof.

FIG. 7 is a top plan view of the interposer substrate in a semiconductor module according to a second embodiment of the present invention.

FIG. 8 is a sectional view of a portion of a semiconductor module according to a third embodiment of the present invention, showing the configuration of the interposer substrate.

FIG. 9 is a top plan view of the interposer substrate in the semiconductor module of the third embodiment.

FIG. 10 is a sectional view of a semiconductor module according to a fourth embodiment of the present invention.

FIGS. 11A and 11B are top and bottom plan views of a conventional semiconductor module.

FIG. 12 is a sectional views of the conventional semiconductor module taken along line XII-XII in FIG. 11A.

### PREFERRED EMBODIMENT OF THE INVENTION

Now, the present invention is more specifically described with reference to accompanying drawings, wherein similar constituent elements are designated by similar reference numerals throughout the drawings.

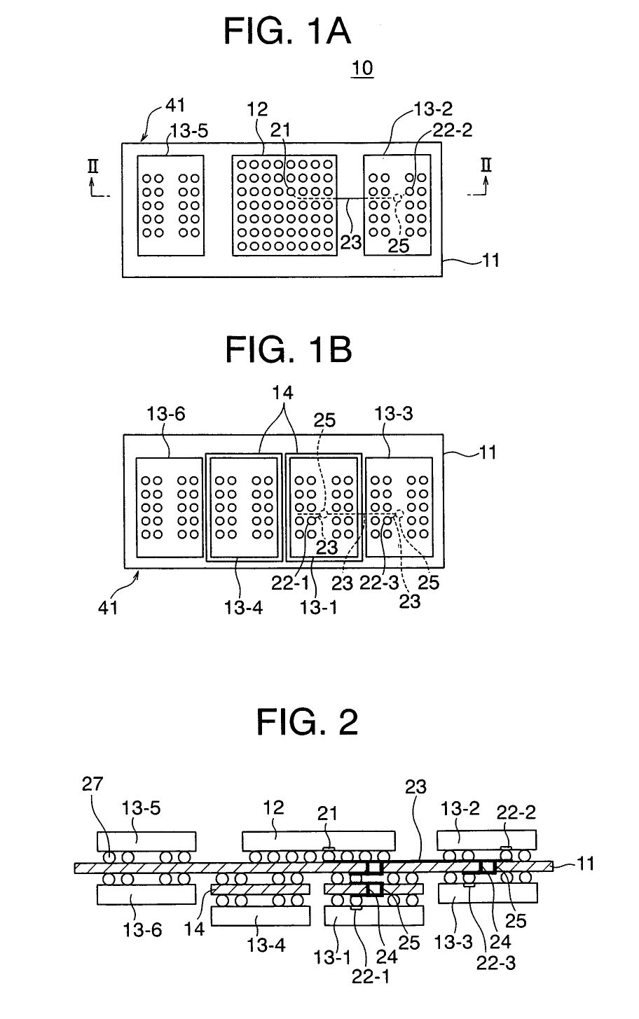

FIGS. 1A and 1B show a semiconductor module according to a first embodiment of the present invention. The semiconductor module, generally designated by numeral 10, includes a wiring board 11, such as a printed circuit board, a driver chip (driver IC chip) 12, a plurality of memory chips (memory IC chips) 13 driven by the driver chip 12, and a plurality of interposer substrates 14 interposing between the wiring board 11 and some of the memory chips 13.

The driver chip 12 is disposed on the central area of the top surface of the wiring board 11, and the memory chips 13 (13-1 to 13-6) are disposed on/above the top and bottom surfaces of the wiring board 11 in a symmetric arrangement. In the present embodiment, two memory chips 13-1 and 13-4 are mounted on the central area of the bottom surface of the wiring board 11 with an intervention of the respective interposer substrates 14. The driver chip 12 and other memory chips 13-2, 13-3, 13-5 and 13-6 are directly mounted on the wiring board 11.

In FIGS. 1A and 1B, terminals 21 of the driver chip 12 and terminals 22 of the memory chips 13 are specifically shown, although those terminals 21, 22 are not formed on the exposed top surface of the memory chips 13. For example, the driver chip 12 includes 200 terminals whereas the memory chips 13 each include 64 terminals. The terminals 21 of the driver chip 12 and the terminals 22 of the memory chips 13 are connected via interconnect lines formed within the wiring board 11 and interposer substrate 14, the interconnect lines including command signal lines, address signal lines, data signal input lines (Din) and data signal output lines (Dout).

FIG. 2 shows the semiconductor module of the present embodiment in a sectional view taken along line II-II in FIG. 1A. In FIGS. 1A and 1B, a specific address signal line 23, which connects the driver chip 12 and memory chips 13-1 to 13-3 together and is associated with via-lines 25, is shown by dotted line, whereas in FIG. 2, the specific signal line 23 is shown by a thick line together with the associated via-lines 25.

The wiring board 11 includes, for example, four insulation layers and five interconnect layers. Via holes 24 each penetrate at least one of the insulation layers and receive therein a via-line 25. The via-lines 25 connect together the interconnect lines formed in different interconnect layers.

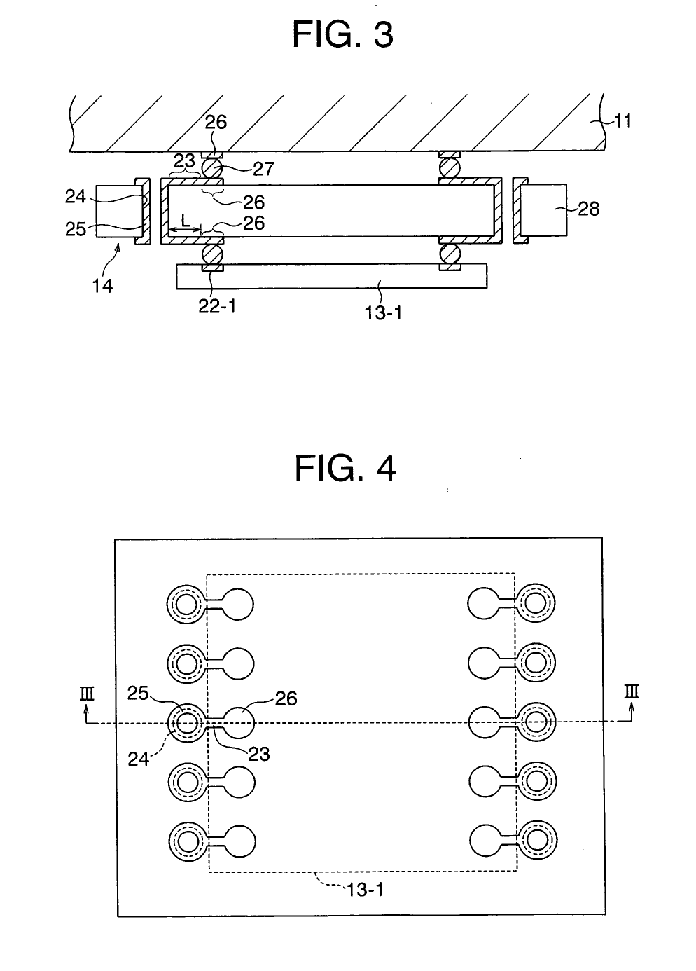

FIG. 3 shows the interposer substrate 14 interposing between the wiring board 12 and the memory chip 13-1. The interposer substrate 14 includes a signal insulation layer 28 and two interconnect layers formed on the top and bottom surfaces of the interposer substrate 14 and connected together by via-lines 25 formed in via-holes 24 penetrating the interposer substrate 14.

Back to FIG. 2, the IC chips 12, 13 are configured as ball-grid-array IC packages using solder balls 27. Thus, the terminals 21, 22 of the IC chips 12, 13 are connected to the terminals 21 of the wiring board 11 and interposer substrate 14 by solder balls 27. Similarly, the terminals of the interposer substrate 14 are connected to the terminals of the wiring board 11 and memory IC chip 13 by solder balls 27.

The interconnect lines 23, terminals 26 and via-lines 25 are made of copper, for example, and the insulation layers disposed between adjacent interconnect layers are made of glass-epoxy resin. The surface of the terminals is plated with gold. The interposer substrate 14 is made of an insulation substance same as the insulation substance of the insulation layers of the wiring board 11, whereby the interposer substrate 14 has a thermal expansion coefficient similar to that of the wiring board 11.

FIG. 4 shows a top plan view of the interposer substrate 14. FIG. 3 corresponds to the section taken along line III-III in FIG. 4. The configuration of bottom surface of the interposer substrate 14 is in a plane symmetry with the configuration of the top surface. The terminal 26 and interconnect line 23 on the top surface, the via-line 25 in the via-hole 24, and the terminal 26 and interconnect line 23 on the bottom surface are formed as an integral body.

In an exemplified configuration, the interconnect lines 23 between the via-lines 25 and the terminals 26 are straight and have a length (L) of 5 mm, and the insulator body 28 of the interposer substrate has a thickness of around 0.3 mm, whereby the total line length in the interposer substrate 14 is roughly 10 mm by neglecting the thickness of the insulator body 28. The total line length in the interposer substrate 14 is adjusted by controlling the length L of the straight interconnect lines 23.

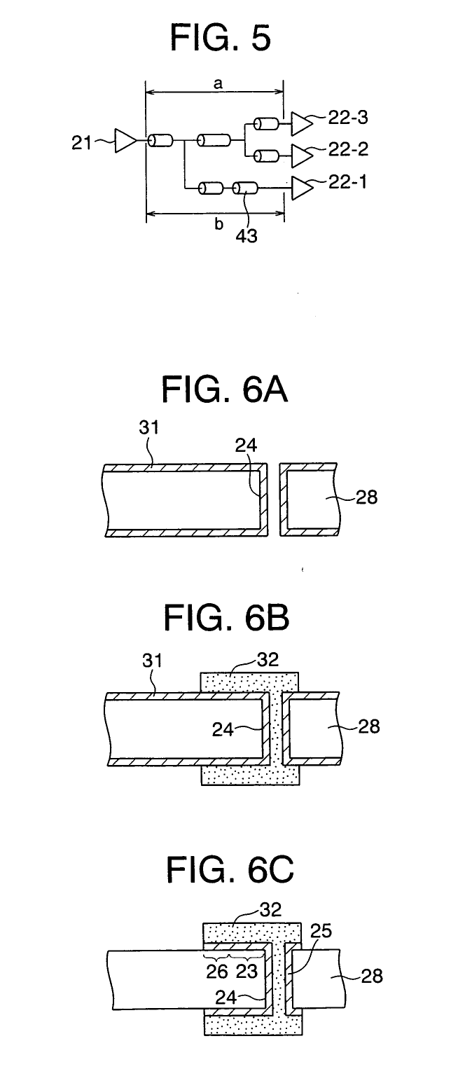

FIG. 5 shows an address signal line connecting the terminal 21 of the driver chip 12 to terminals 22-1 to 22-3 of the memory chips 13-1 to 13-3, wherein numeral 43 denotes an interconnect line of a single layer or a single branch line. The total line length “b” between the driver chip 12 and the memory chip 13-1 is adjusted by inserting the interconnect lines 43 of the interposer substrate 14 so that the total line length “b” equals to the total line length “a” between the driver chip 12 and the memory chips 13-2 and 13-3.

FIGS. 6A to 6C consecutively show steps of fabricating the interposer substrate 14. In fabrication of the interposer substrate 14, via-holes 24 are formed to penetrate the insulator body 28 of the interposer substrate 14. A metallic film 31 is then formed on the top and bottom surfaces of the insulator body 28 and the sidewall of the via-holes 24, as shown in FIG. 6A. Subsequently, a mask pattern 32 having a pattern of the interconnect lines and terminals is formed by a known photolithographic and etching technique on the top and bottom surfaces of the insulator body 28 while filling the internal of the via-holes 24, as shown in FIG. 6B. Thereafter, an etching process is conducted using the mask pattern 32 as an etching mask to configure the interconnect lines 23, terminals 26 and via-lines 25, as shown in FIG. 6C.

Subsequently, the mask pattern 32 is removed to obtain the interposer substrate 14 shown in FIG. 3. It is to be noted that an insulator body 28 manufactured to have a metallic film on both the top and bottom surfaces thereof may be used instead to save the cost for manufacturing the interposer substrate 14. In this case, the via-lines 25 are formed separately from the interconnect lines 23 and terminals 26

In the semiconductor module 40 of the present embodiment, the interposer substrate 14 interposing between the wiring board 11 and some memory chips 13-1, 13-4 provides a uniform line length among the memory chips 13-1 to 13-6 with respect to the driver chip 12. This provides a uniform propagation delay among the memory chips 13, thereby suppressing occurrence of the interference by a reflected wave and thus suppresses an error in the operation of the semiconductor module.

The terminals 26 formed on the top surface of the interposer substrate 14 overlap with the terminals 26 formed on the bottom surfaces of the interposer substrate 14 as viewed normal to the substrate 14. This allows the interposer substrate 14 to interpose between the wiring substrate 11 and any of the standard memory chips 13, which are manufactured without consideration of presence or absence of the interposer substrate 14. In addition, the interposer substrate 14 may be used only in the vicinity of the driver chip 12 wherein the interconnect lines are arranged with a higher density. This reduces the cost of the wiring board 11 which otherwise has a larger thickness.

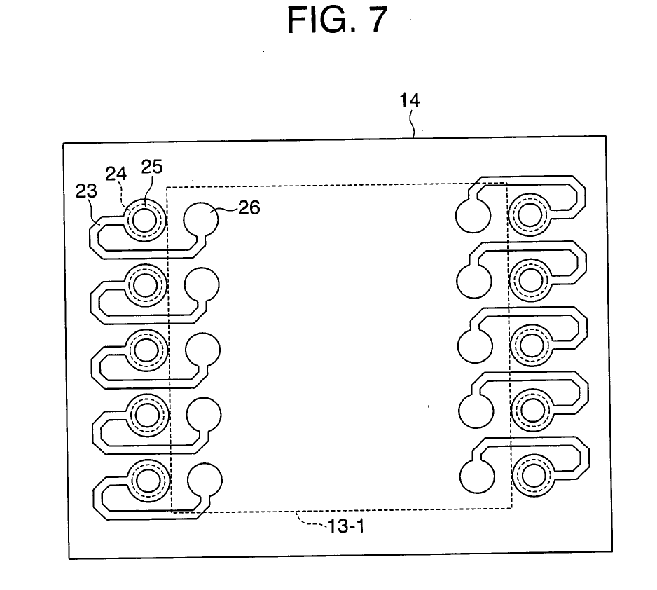

FIG. 7 shows a top plan view of an interposer substrate used in a semiconductor module according to a second embodiment of the present invention. In the second embodiment, the interposer substrate 14 includes interconnect lines 23 each having a detour path on both the top and bottom surfaces of the interposer substrate 14. The detour path adjusts the total line length of the interposer substrate 14 between the terminals 26 of the wiring board 11 and the terminals 26 of the memory chips 13.

In the first and second embodiments, the interposer substrate 14 has two interconnect layers formed on the top and bottom surfaces of the interposer substrate.

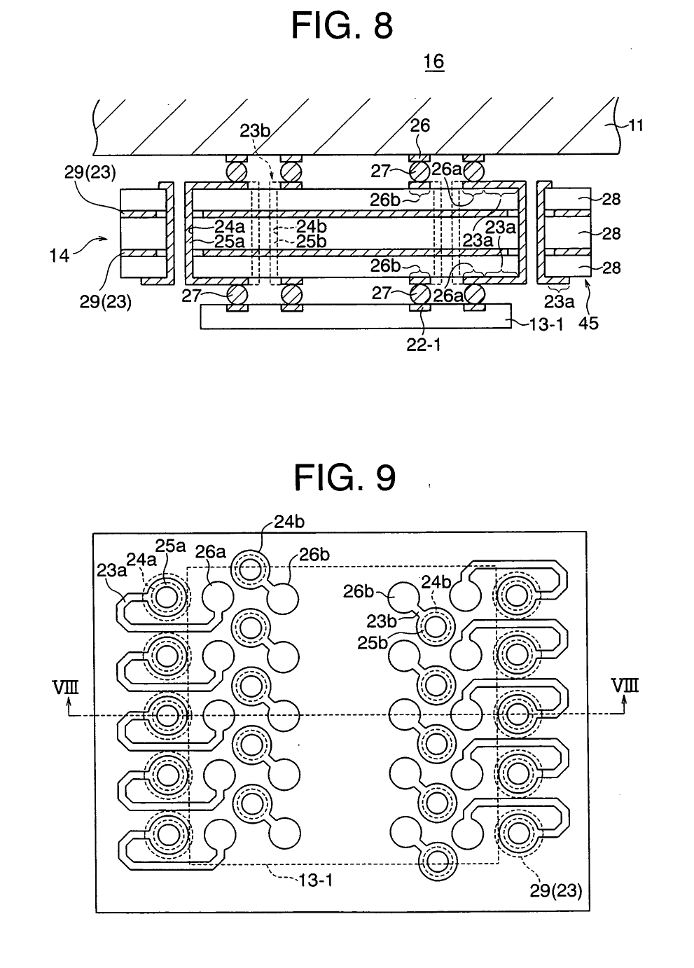

FIG. 8 is a sectional view of a semiconductor module according to a third embodiment of the present invention, showing the vicinity of the interposer substrate. The interposer substrate 14 in the present embodiment has a plurality (3) of insulation layers 28 and four interconnect layers including top and bottom interconnect layers. The top and bottom interconnect layers each include address signal lines 23, address signal terminals 26a, ground terminal 26b. Via-holes 24a and 24b are disposed in the vicinity of the address signal terminals 26a and the ground terminals 26b, respectively, and receive therein via-lines 25a and 25b.

Interconnect lines 23a, 23b connect terminals 26a, 26b and via-lines 25a, 25b together on both top and bottom surfaces. Two interconnect layers 29 sandwiched between adjacent insulation layers 28 connect to ground via-lines 25b to thereby configure the interconnect layers 29 as reference layers or ground layers. The reference layers 29 are formed as a substantially planar shape except for the location of the signal via-holes 24a and the vicinity thereof.

FIG. 9 shows a top plan view of the interposer substrate 14 shown in FIG. 8. FIG. 8 corresponds to the section taken along line VIII-VIII in FIG. 9. Signal terminals 26a and ground terminals 26b are arranged in pair along both the edges of the top surface of the interposer substrate 14 to configure pair terminals of microstrip waveguides. Interconnect lines 23a have a detour path around the via-holes 24a for connecting the signal terminals 26a and signal via-lines 24a together while increasing the total line length, whereas ground lines 23b have a straight path connecting the ground terminals 26b and ground via-lines 25b together. On the bottom surface of the interposer substrate 14, the interconnect lines 23a, 23b have a straight path connecting the terminals 26a, 26b and the via-lines 25a, 25b together.

The signal interconnect liens 23a disposed on the top and bottom surfaces of the interposer substrate 14 and the reference layer or ground layer 29 adjacent to the interconnect lines 23a in combination configure microstrip waveguides having a reduced and fixed impedance. It is to be noted that the reference layers 29 may be connected to the power source line (Vcc) instead of the ground line. The ground line of the microstrip waveguide may be disposed for each two of the address signal lines, for example, instead of the one-to-one correspondence.

In the above embodiment, the length of the address signal lines is adjusted; however, the length of other interconnect lines such as the command signal lines (control signal lines), data signal input lines, data signal output lines and clock signal lines may be adjusted similarly. This provides a uniform propagation delay among the memory chips, thereby suppressing a malfunction in the semiconductor module. In addition, the length of a species of signal lines may be also adjusted in relation to the length of other species of signal lines so that a suitable timing can be obtained in the semiconductor module to suppress a malfunction therein.

In the above embodiment, the terminals on the bottom surface of the interposer substrate overlap with the terminals on the top surface thereof as viewed normal to the surface of the wiring board. However, it is not essential to have such an overlapping configuration in the present invention. Arrangement of the terminals without using the overlapping configuration provides a larger design choice of the arrangement of the terminals on the memory chips.

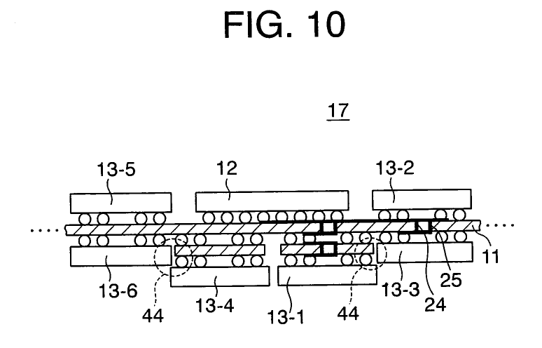

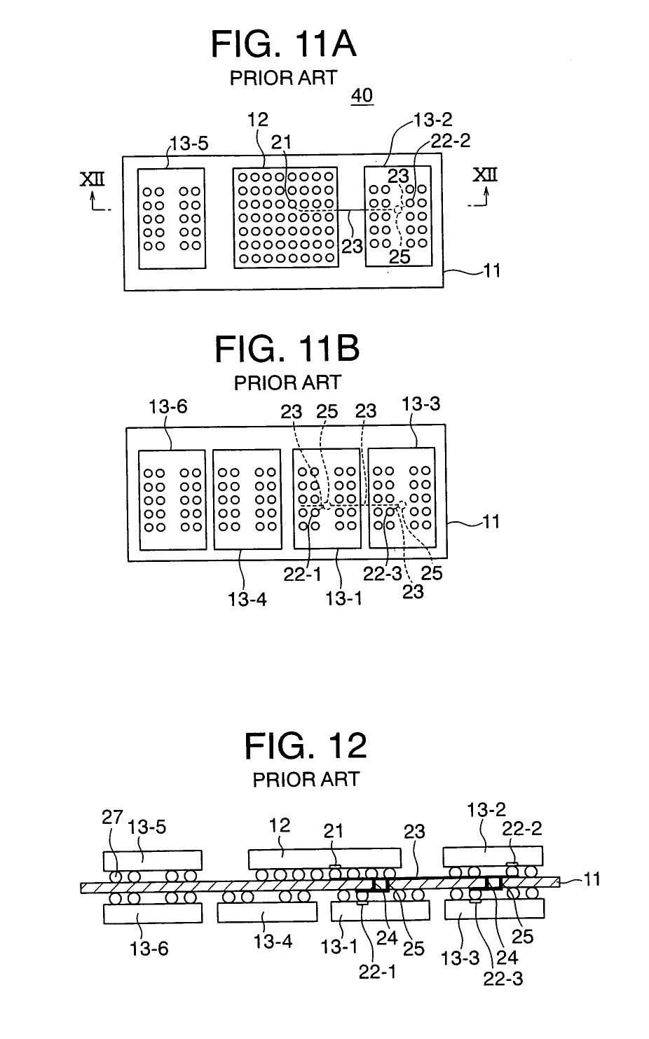

FIG. 10 shows a semiconductor module according to a fourth embodiment of the present invention. The semiconductor module, generally designated by numeral 17, is similar to the semiconductor module of the first embodiment except that the total of the thickness of the interposer substrate 14 and the thickness of the solder balls 27 connecting together the interposer substrate 14 and memory chips 13-1, 13-4 is larger than the thickness of the memory chips 13-3, 13-6. Memory chips 13-1 and 13-4 have an edge overhanging an edge of adjacent memory chips 13-3 and 13-6, respectively, as shown in the circles specified by numeral 44 in FIG. 10.

In the semiconductor module 17 of the present embodiment, the overhanging of the edge portion of the memory chips allows the memory chips to be arranged in a smaller occupied area for the wiring board 11, thereby improving the mounting efficiency of the memory chips 13 in the semiconductor module 17.

As described above, the present invention may have the configurations as summarized below. If the plurality of IC chips include a driver IC chip and a plurality of driven IC chips driven by the driver IC chip, the driver IC chip may be configured as the second IC chip, and each of the driven IC chips may be configured as the first IC chip or second IC chip.

In an alternative, if the plurality of IC chips include a driver IC chip and a plurality of driven IC chip driven by the driver IC chip, the driver IC chip may be configured as the first IC chip, and each of the driven IC chips may be configured as the first IC chip or second IC chip.

In the above configuration, the first IC chip configuring the driven IC chip may be disposed farther from the driver IC chip than the second IC chip configuring the driven IC chip.

The wiring board may include a plurality of species of signal lines including an address signal line, a data signal line, a clock signal line and a control signal line connected between the driver IC chip and each of a plurality of the driven IC chips, and one of the species of signal lines may have a uniform line length among signal lines for the plurality of driven IC chips. This configuration suppresses a difference in the propagation delay of the signal lines among the IC chips and thus suppresses occurrence of the signal interference.

The interposer substrate may include a microstrip waveguide or microstrip line. The microstrip waveguide provides a reduced impedance for the signal lines.

One of the at least one second IC chip may have an edge overhanging an edge of one of the at least one first IC chip by employing a configuration wherein the effective thickness of the interposer substrate is larger than the thickness of the first IC chips.

The interposer substrate may include a pair of terminals on top and bottom surfaces thereof, the pair of terminals being connected with each other via an interconnect line in the interposer substrate and overlapping each other as viewed in the thickness direction thereof. In this case, the interposer substrate may be disposed without changing the arrangement of the terminals of the conventional memory chips.

In an alternative, the pair of terminals formed on the top and bottom surfaces and connected with each other via an interconnect line in the interposer substrate may be deviated from each other as viewed in the thickness direction thereof, thereby obtaining a larger design choice.

The interposer substrate may include a single or a plurality of interconnect layer, for achieving a desired uniform line length. In addition, the interposer substrate may include a film insulator body. A single memory chip or a plurality of memory chips may be disposed on a single interposer substrate.

Since the above embodiments are described only for examples, the present invention is not limited to the above embodiments and various modifications or alterations can be easily made therefrom by those skilled in the art without departing from the scope of the present invention.

What is claimed is:

1. A semiconductor module comprising a wiring board, an interposer substrate mounted on said wiring board, and a plurality of IC chips including at least one first IC chip directly mounted on said wiring board and at least one second IC chip mounted on said interposer substrate and connected to interconnect lines in said wiring board via said interposer substrate.

2. The semiconductor module according to claim 1, wherein said plurality of IC chips include a driver IC chip and a plurality of driven IC chip driven by said driver IC chip, said driver IC chip is configured as said second IC chip, and each of said driven IC chips is configured as said first IC chip or second IC chip.

3. The semiconductor module according to claim 1, wherein said plurality of IC chips include a driver IC chip and a plurality of driven IC chip driven by said driver IC chip, said driver IC chip is configured as said first IC chip, and each of said driven IC chips is configured as said first IC chip or second IC chip.

4. The semiconductor module according to claim 3, wherein said first IC chip configuring said driven IC chip is disposed farther from said driver IC chip than said second IC chip configuring said driven IC chip.

5. The semiconductor module according to claim 4, wherein said wiring board includes a plurality of species of signal lines including an address signal line, a data signal line, a clock signal line and a control signal line connected between said driver IC chip and each of a plurality of said driven IC chips, and said species of signal lines has a uniform line length among said plurality of driven IC chips.

6. The semiconductor module according to claim 1, wherein said interposer substrate includes a microstrip waveguide.

7. The semiconductor module according to claim 1, wherein one of said at least one second IC chip has an edge overhanging an edge of one of said at least one first IC chip.

8. The semiconductor module according to claim 1, wherein said interposer substrate includes a pair of terminals on top and bottom surfaces thereof, said pair of terminals being connected with each other via an interconnect line in said interposer substrate and overlapping each other as viewed in the thickness direction thereof.

9. The semiconductor module according to claim 1, wherein said interposer substrate includes a pair of terminals on top and bottom surfaces thereof, said pair of terminals being connected with each other via an interconnect line in said interposer substrate and deviated from each other as viewed in the thickness direction thereof.

10. The semiconductor module according to claim 1, wherein said interposer substrate includes a plurality of interconnect layers.

11. The semiconductor module according to claim 1, wherein said interposer substrate includes a film insulator body.
